(19) United States
(12) Patent Application Publication
(10) Pub. No.: US 2026/0247814 A1
(43) Pub. Date: Aug. 20, 2026

(54) DISPLAY DEVICE AND ELECTRONIC DEVICE COMPRISING THE SAME

(71) Applicant: Samsung Display Co., Ltd., Yongin-si (KR)

(72) Inventors: Changwook KIM, Yongin-si (KR); Chan Young KIM, Yongin-si (KR); JUNHEE LEE, Yongin-si (KR); Choong Youl IM, Yongin-si (KR); Beohm Rock CHOI, Yongin-si (KR); Seong-Yong HWANG, Yongin-si (KR)

(21) Appl. No.: 19/325,227

(22) Filed: Sep. 10, 2025

(30) Foreign Application Priority Data
Feb. 19, 2025 (KR) 10-2025-0021656

(51) Int. Cl. H10K 59/131; H10D 86/40; H10D 86/60; H10K 59/121; H10K 59/122; H10K 59/60; H10K 59/80

(52) U.S. Cl. CPC H10K 59/131; H10K 59/1213; H10K 59/122; H10K 59/60; H10K 59/878; H10D 86/441; H10D 86/60

(57) ABSTRACT

A display device includes: a display panel including a display area and a component area surrounded by the display area and including light sensor areas; and an optical element on a rear surface of the component area, the display area including: a transistor on a substrate, a first electrode on the transistor, a pixel defining layer overlapping a portion of the first electrode, a light emitting layer overlapping the first electrode, and a second electrode on the light emitting layer, the light sensor area including: a metal line on the substrate, an extension portion extending from the first electrode, an insulating layer between the metal line and the extension portion, the pixel defining layer on the extension portion and including a first opening, and a second electrode on the pixel defining layer, the extension portion overlapping at least a portion of the metal line in a plan view.

### CROSS-REFERENCE TO RELATED APPLICATIONS

The present application claims priority to and the benefit of Korean Patent Application No. 10-2025-0021656, filed on Feb. 19, 2025, in the Korean Intellectual Property Office, the entire disclosure of which is incorporated herein by reference.

### BACKGROUND

### 1. Field

Aspects of some embodiments of the present disclosure relate to a display device and an electronic device comprising the same.

### 2. Description of the Related Art

A display device is a device for displaying images on a screen, and includes liquid crystal display devices, organic light emitting display devices, and the like. Such display devices may be used in various electronic devices such as mobile phones, navigation systems, digital cameras, electronic books, portable game consoles, or various terminals.

In small electronic devices, for example, mobile phones, optical elements such as cameras or optical sensors may be located in a peripheral bezel area of a screen. However, as the screen size gradually increases, the peripheral area of the display area may decrease. Accordingly, technology for arranging a camera or an optical sensor on the rear surface of the screen is being developed.

The above information disclosed in this Background section is only for enhancement of understanding of the background and therefore the information discussed in this Background section does not necessarily constitute prior art.

### SUMMARY

Aspects of some embodiments include a display device that increases the amount of light provided to the rear surface of a display panel and an electronic device comprising the same.

A display device according to some embodiments includes a display panel including a display area and a component area surrounded by the display area and including a plurality of light sensor areas; and an optical element positioned on a rear surface of the component area, wherein the display area includes a transistor positioned on a substrate, a first electrode positioned on the transistor, a pixel defining layer overlapping a portion of the first electrode, a light emitting layer overlapping the first electrode, and a second electrode positioned on the light emitting layer, and the light sensor area includes a metal line positioned on the substrate, an extension portion extending from the first electrode, an insulating layer positioned between the metal line and the extension portion, the pixel defining layer positioned on the extension portion and including a first opening, and a second electrode positioned on the pixel defining layer, wherein the extension portion overlaps at least a portion of the metal line in a plan view.

According to some embodiments, the first component area may include a red light emission area, a green light emission area, and a blue light emission area.

According to some embodiments, the extension portion may include a first portion extending from the first electrode toward the first opening in a plan view, and a second portion and a third portion respectively protruding from the first portion, wherein the first portion may be between the second portion and the third portion.

According to some embodiments, the second portion and the third portion may protrude in different directions.

According to some embodiments, each of the first portion, the second portion, and the third portion may overlap at least a portion of the metal line.

According to some embodiments, the extension portion may be arranged along an edge of the metal line.

According to some embodiments, the transistor may include a semiconductor layer positioned on the substrate, a gate electrode overlapping a portion of the semiconductor layer, and a source electrode and a drain electrode electrically connected to the semiconductor layer, and the metal line may be positioned on the same layer as at least one of the gate electrode or the source electrode.

According to some embodiments, the metal line may be electrically connected to at least one of the gate electrode or the source electrode.

According to some embodiments, the insulating layer may include at least two layers.

According to some embodiments, the pixel defining layer positioned in the light sensor area may cover an end of the extension portion.

According to some embodiments, the second electrode extending from the display area may contact the insulating layer at the first opening.

A display device according to some embodiments includes a display panel including a display area and a component area surrounded by the display area and including a plurality of light sensor areas; and an optical element positioned on a rear surface of the component area, wherein the display area includes a transistor positioned on a substrate, a first electrode positioned on the transistor, a pixel defining layer overlapping a portion of the first electrode, a light emitting layer overlapping the first electrode, and a second electrode positioned on the light emitting layer, and the light sensor area includes the pixel defining layer extending from the display area and including a first opening, a reflective layer positioned between adjacent first electrodes and surrounding the first opening, and a second electrode positioned on the pixel defining layer, wherein the reflective layer is positioned on the same layer as the first electrode and spaced apart from the first electrode.

According to some embodiments, the reflective layer may include a second opening, and a size of the second opening may be larger than a size of the first opening.

According to some embodiments, the first component area may include a red light emission area, a green light emission area, and a blue light emission area, and the reflective layer may be positioned between the red light emission area, the green light emission area, and the blue light emission area.

According to some embodiments, the transistor may include a semiconductor layer positioned on the substrate, a gate electrode overlapping a portion of the semiconductor layer, and a source electrode and a drain electrode electrically connected to the semiconductor layer, and the light sensor area may further include a metal line positioned on a same layer as at least one of the gate electrode or the source electrode.

According to some embodiments, the reflective layer may overlap at least a portion of the metal line.

According to some embodiments, the metal line may be electrically connected to at least one of the gate electrode or the source electrode.

According to some embodiments, the display device may further include an insulating layer positioned between the metal line and the reflective layer, and a distance (d) between an end of the metal line and an end of the reflective layer may satisfy Equation (1) below:

$$d < t \cdot tan Θ \qquad Equation ( 1 )$$

where t is a minimum distance between an upper surface of the metal line and a lower surface of the reflective layer, and Θ is an incident angle of light on the metal line.

According to some embodiments, the insulating layer may include at least two layers.

According to some embodiments, the pixel defining layer positioned in the light sensor area may cover an end of the reflective layer.

An electronic device according to some embodiments includes a display device, wherein the display device includes a display panel including a display area and a component area surrounded by the display area and including a plurality of light sensor areas; and an optical element positioned on a rear surface of the component area, wherein the display area includes a transistor positioned on a substrate, a first electrode positioned on the transistor, a pixel defining layer overlapping a portion of the first electrode, a light emitting layer overlapping the first electrode, and a second electrode positioned on the light emitting layer, and the light sensor area includes a metal line positioned on the substrate, an extension portion extending from the first electrode, the pixel defining layer positioned on the extension portion and including a first opening, and a second electrode positioned on the pixel defining layer, wherein the extension portion overlaps at least a portion of the metal line.

According to some embodiments, the electronic device may be at least one of a smartphone, a tablet PC, a laptop, a TV, a desktop monitor, smart glasses, a head mount display, a smart watch, an instrument panel, a center fascia, a CID (Center Information Display), or a room mirror display.

According to some embodiments, a display device with a relatively increased amount of light may be provided to the rear surface of a display panel and an electronic device including the same may be provided.

### BRIEF DESCRIPTION OF THE DRAWINGS

FIG. 1 is a block diagram of an electronic device according to some embodiments.

FIG. 2 shows schematic diagrams of electronic devices according to some embodiments.

FIG. 3 is a schematic perspective view illustrating a use state of an electronic device according to some embodiments.

FIG. 4 is an exploded perspective view of an electronic device according to some embodiments.

FIG. 5 is a perspective view of an electronic device according to some embodiments.

FIG. 6 is a plan view of a partial area of a display device according to some embodiments.

FIG. 7 is a cross-sectional view of a display area according to some embodiments.

FIG. 8 is a plan view of a first component area according to some embodiments.

FIG. 9 is a cross-sectional view of a light sensor area according to some embodiments.

FIG. 10 is a view illustrating a path of light incident in a light sensor area according to some embodiments.

FIG. 11 is a schematic cross-sectional view of a light sensor area according to some embodiments.

FIG. 12 is a plan view of a first component area according to some embodiments.

FIG. 13 is a plan view of a first component area according to some embodiments.

FIG. 14 is a schematic cross-sectional view of a light sensor area according to some embodiments.

FIG. 15 is a schematic diagram illustrating light incident on a display panel according to some embodiments.

FIG. 16 is a schematic diagram illustrating light incident on a display panel according to a comparative example.

### DETAILED DESCRIPTION

Hereinafter, aspects of some embodiments of the present disclosure will be described in more detail with reference to the accompanying drawings so that those skilled in the art can more easily implement them. The present disclosure may be embodied in many different forms and is not limited to the embodiments described herein.

To more clearly describe embodiments according to the present disclosure, parts irrelevant to the description have been omitted, and the same reference numerals are assigned to the same or similar components throughout the specification.

In addition, the size and thickness of each component shown in the drawings are arbitrarily shown for convenience of description, so the present disclosure is not necessarily limited to what is shown. In the drawings, the thickness is enlarged to clearly express various layers and regions. And in the drawings, for convenience of description, the thickness of some layers and regions is exaggerated.

In addition, in case that a part such as a layer, film, region, or plate is said to be “on” or “above” another part, this includes not only the case where it is “directly on” another part but also the case where there is another part in between. Conversely, in case that a part is said to be “directly on” another part, it means that there is no other part in between. In addition, being “on” or “above” a reference part means being positioned above or below the reference part, and does not necessarily mean being positioned “on” or “above” in the opposite direction of gravity.

In addition, throughout the specification, in case that a part is said to “include” a certain component, this means that it may further include other components rather than excluding other components unless otherwise stated.

In addition, throughout the specification, “in a plan view” means in case that the target part is viewed from above, and “in a cross-sectional view” means in case that a cross section obtained by vertically cutting the target part is viewed from the side.

A display device according to some embodiments may be applied to various electronic devices. An electronic device according to some embodiments includes a display device to be described later, and may further include a module or device having other additional functions in addition to the display device.

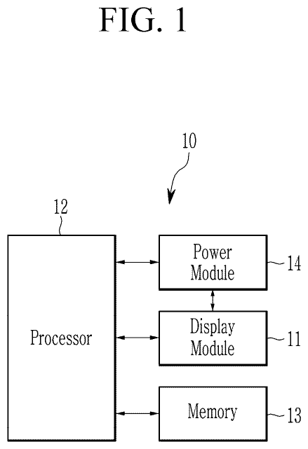

FIG. 1 is a block diagram of an electronic device according to some embodiments.

Referring to FIG. 1, an electronic device 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information utilized for the operation of the processor 12 or the display module 11. In the event that the processor 12 executes an application stored in the memory 13, an image data signal and/or an input control signal may be transmitted to the display module 11, and the display module 11 may process the provided signal to output image information through a display screen.

The power module 14 may include a power supply module such as a power adapter or a battery device, and a power conversion module that converts power supplied by the power supply module to generate power necessary for the operation of the electronic device 10.

At least one of each component of the electronic device 10 described above may be included in the display device according to the above-described embodiments. In addition, some of the individual modules functionally included in one module may be included in the display device and others may be provided separately from the display device. For example, the display device may include the display module 11, and the processor 12, the memory 13, and the power module 14 may be provided in the form of other devices in the electronic device 10 rather than the display device.

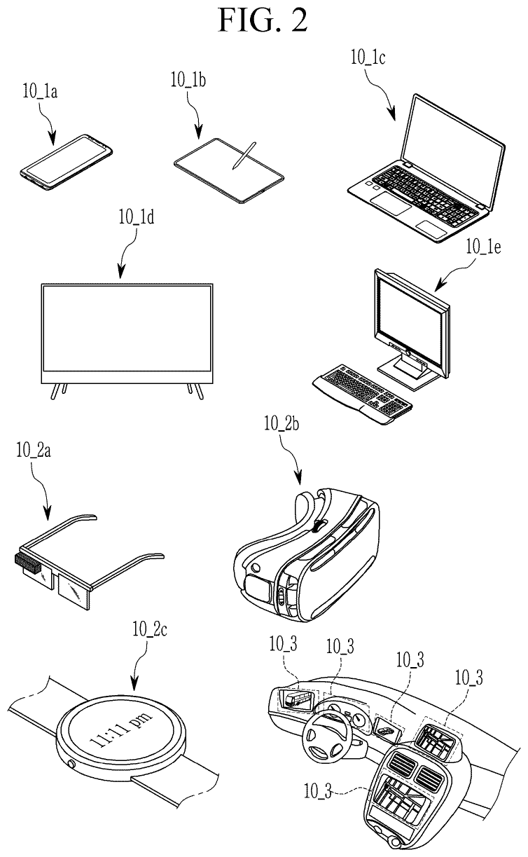

FIG. 2 shows schematic diagrams of electronic devices according to some embodiments.

Referring to FIG. 2, various electronic devices to which the display device according to the embodiments is applied may include not only electronic devices for image display such as a smartphone (10_1a), a tablet PC (10_1b), a laptop (10_1c), a TV (10_1d), and a desktop monitor (10_1e), but also wearable electronic devices including a display module such as smart glasses (10_2a), a head mount display (10_2b), and a smart watch (10_2c), and vehicle electronic devices (10_3) including a display module such as an instrument panel of a vehicle, a center fascia, a CID (Center Information Display) located on a dashboard, and a room mirror display.

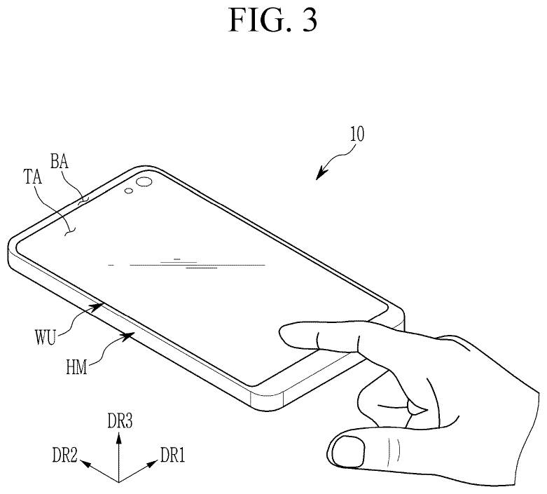

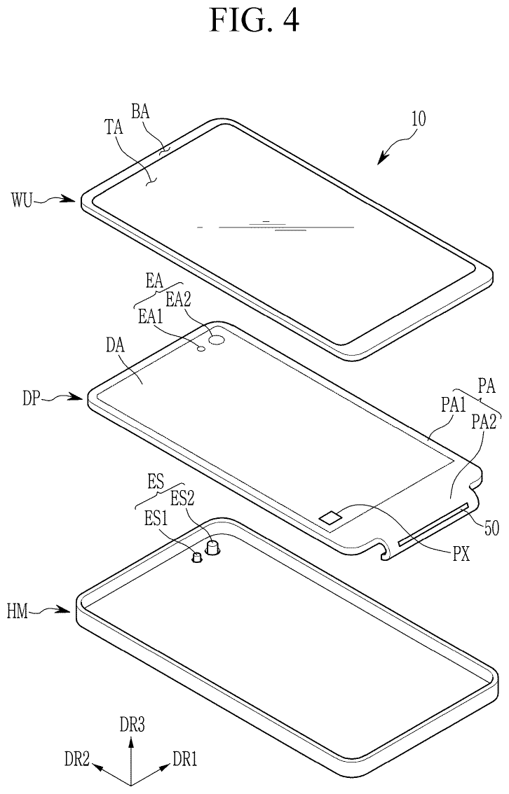

Hereinafter, a schematic structure of an electronic device will be described in more detail with reference to FIGS. 3 to 4. FIG. 3 is a schematic perspective view illustrating a use state of an electronic device according to some embodiments, and FIG. 4 is an exploded perspective view of an electronic device according to some embodiments.

Referring to FIG. 3, the electronic device 10 may display an image in a third direction DR3 on a display surface parallel to each of a first direction DR1 and a second direction DR2. The display surface on which images are displayed may correspond to the front surface of the electronic device 10, and may correspond to the front surface of the cover window WU. The images may include static images (e.g., still images) as well as dynamic images (e.g., video images).

According to some embodiments, the front surface (or upper surface) and the rear surface (or lower surface) of each member are defined based on the direction in which the image is displayed. The front surface and the rear surface are opposing each other in the third direction DR3, and the normal direction of each of the front surface and the rear surface may be parallel to the third direction DR3. The separation distance between the front surface and the rear surface in the third direction DR3 may correspond to the thickness of the display panel in the third direction DR3.

The electronic device 10 according to some embodiments may detect a user's input applied from the outside (refer to the hand in FIG. 3). The user's input may include various types of external inputs such as a part of the user's body, light, heat, or pressure. According to some embodiments, the user's input is illustrated as the user's hand applied to the front surface. However, embodiments according to the present disclosure are not limited thereto. The user's input may be provided in various forms, and also, the electronic device 10 may detect the user's input applied to the side or rear surface of the electronic device 10 according to the structure of the electronic device 10.

Referring to FIGS. 3 and 4, the electronic device 10 may include a cover window WU, a housing HM, a display panel DP, and an optical element ES. According to some embodiments, the cover window WU and the housing HM may be combined to constitute the exterior of the electronic device 10.

The cover window WU may include an insulating panel. For example, the cover window WU may be made of glass, plastic, or a combination thereof.

The front surface of the cover window WU may define the front surface of the electronic device 10. The transmission area TA may be an optically transparent area. For example, the transmission area TA may be an area having a visible light transmittance of about 90% or more.

The blocking area BA may define the shape of the transmission area TA. The blocking area BA may be adjacent to the transmission area TA and may surround the transmission area TA. The blocking area BA may be an area having a relatively low light transmittance compared to the transmission area TA. The blocking area BA may include an opaque material that blocks light. The blocking area BA may have a color (e.g., a set or predetermined color). The blocking area BA may be defined by a bezel layer provided separately from the transparent substrate defining the transmission area TA, or may be defined by an ink layer formed by being inserted or colored in the transparent substrate.

The display panel DP may include a display panel DP displaying images and a driver 50. The display panel DP may include a front surface including a display area DA and a non-display area PA. The display area DA may be an area where pixels operate to emit light according to electrical signals.

According to some embodiments, the display area DA is an area where images are displayed including pixels, and at the same time, may be an area where an external input is sensed by a touch sensor positioned above the pixels in the third direction DR3.

The transmission area TA of the cover window WU may at least partially overlap the display area DA of the display panel DP. For example, the transmission area TA may overlap the front surface of the display area DA or at least a portion of the display area DA. Accordingly, the user may view images through the transmission area TA or provide an external input based on the images. However, embodiments according to the present disclosure are not limited thereto. For example, an area where images are displayed and an area where an external input is sensed may be separated from each other in the display area DA.

The non-display area PA of the display panel DP may at least partially overlap the blocking area BA of the cover window WU. The non-display area PA may be an area covered by the blocking area BA. The non-display area PA is adjacent to the display area DA and may surround (e.g., in a periphery or outside a footprint of) the display area DA. The non-display area PA does not display images, and driving circuits or driving lines for driving the display area DA may be located in the non-display area PA. The non-display area PA may include a first peripheral area PA1 where the display area DA is located outside, and a second peripheral area PA2 including the driver 50, connection lines, and a bending area. In the embodiments of FIG. 4, the first peripheral area PA1 is located on three sides of the display area DA, and the second peripheral area PA2 is located on the remaining one side of the display area DA.

According to some embodiments, the display panel DP may be assembled in a flat state with the display area DA and the non-display area PA facing the cover window WU. However, embodiments according to the present disclosure are not limited thereto. A portion of the non-display area PA of the display panel DP may be bent. At this time, a portion of the non-display area PA faces the rear surface of the electronic device 10, so that the blocking area BA shown on the front surface of the electronic device 10 may be relatively reduced, and in FIG. 4, the second peripheral area PA2 may be bent and positioned on the rear surface of the display area DA and then assembled.

In addition, the display panel DP may include a component area EA, and specifically, may include a first component area EA1 and a second component area EA2. The first component area EA1 and the second component area EA2 may be at least partially surrounded by the display area DA. The first component area EA1 and the second component area EA2 are shown as being spaced apart from each other, but are not limited thereto and may be at least partially connected. The first component area EA1 and the second component area EA2 may be areas where components using infrared rays, visible light, or sound are located under the component areas.

The display area DA includes a plurality of light emitting diodes and a plurality of pixel circuit units that generate and deliver light emitting currents to each of the plurality of light emitting diodes. Here, one light emitting diode and one pixel circuit unit are referred to as a pixel PX. In the display area DA, one pixel circuit unit and one light emitting diode are formed in a one-to-one manner.

The first component area EA1 may include a transmissive portion (a light sensor area to be described later) through which light and/or sound may transmit and a display portion (a light emission area to be described later) including a plurality of pixels. The transmissive portion is positioned between adjacent pixels and includes a transparent layer through which light and/or sound may transmit. The display portion may be formed to have one unit structure by combining a plurality of pixels, and the transmissive portion may be positioned between adjacent unit structures.

The second component area EA2 includes an area including a transparent layer to allow light to pass through, has no conductive layer or semiconductor layer positioned in the second component area EA2, and may have a structure that does not block light by having a pixel defining layer, a light blocking layer, or the like including a light blocking material and including an opening.

The driver 50 may be mounted on the second peripheral area PA2, and may be mounted on the bending part or positioned on one of the two sides of the bending part. The driver 50 may be provided in the form of a chip.

The driver 50 may be electrically connected to the display area DA to transmit electrical signals to the display area DA. For example, the driver 50 may provide data signals to the pixels PX located in the display area DA. Alternatively, the driver 50 may include a touch driving circuit and may be electrically connected to a touch sensor located in the display area DA. In addition, the driver 50 may be designed to include various circuits in addition to the above-described circuits or to provide various electrical signals to the display area DA.

A pad portion may be positioned at an end of the second peripheral area PA2, and may be electrically connected to a flexible printed circuit board (FPCB) including a driving chip by the pad portion. Here, the driving chip positioned on the flexible printed circuit board may include various driving circuits for driving the electronic device 10 or a connector for power supply, and the like. According to some embodiments, instead of the flexible printed circuit board, a rigid printed circuit board (PCB) may be used.

The optical element ES may be located under the display panel DP. The optical element ES may include a first optical element ES1 overlapping the first component area EA1 and a second optical element ES2 overlapping the second component area EA2.

The first optical element ES1 may be an electronic element using light or sound. For example, the first optical element ES1 may be a sensor that receives and uses light such as an infrared sensor, a sensor that outputs and detects light or sound to measure distance or recognize a fingerprint, a small lamp that outputs light, or a speaker that outputs sound. In the case of an electronic element using light, it is needless to say that light of various wavelength bands such as visible light, infrared light, and ultraviolet light may be used.

The second optical element ES2 may be at least one of a camera, an IR camera, a dot projector, an IR illuminator, or a ToF sensor (Time-of-Flight sensor).

The housing HM may be coupled with the cover window WU. The cover window WU may be located on the front surface of the housing HM. The housing HM may be coupled with the cover window WU to provide an accommodation space (e.g., a set or predetermined accommodation space). The display panel DP and the optical element ES may be accommodated in the accommodation space (e.g., the set or predetermined accommodation space) provided between the housing HM and the cover window WU.

The housing HM may include a material having relatively high rigidity. For example, the housing HM may include glass, plastic, or metal, or may include a plurality of frames and/or plates including a combination thereof. The housing HM may stably protect the components of the electronic device 10 accommodated in the internal space from external impact.

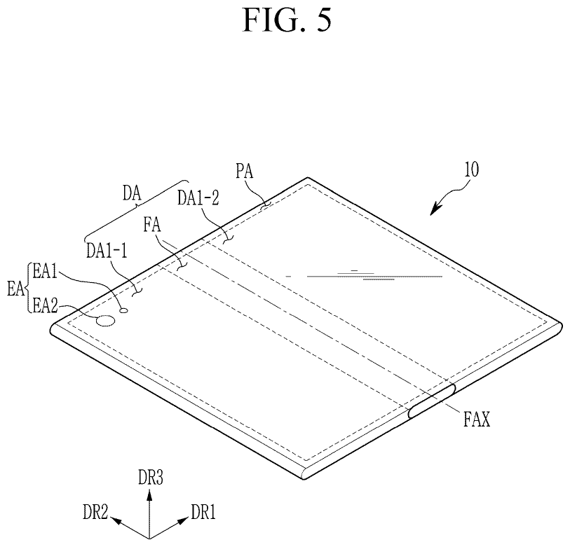

Hereinafter, an electronic device according to some embodiments will be described in more detail with reference to FIG. 5. FIG. 5 is a perspective view schematically illustrating an electronic device according to some embodiments. Description of the same configuration as the above-described components will be omitted.

In the embodiments of FIG. 5, the electronic device 10 illustrates a foldable display device having a structure that is folded through a folding axis FAX.

According to some embodiments, the electronic device 10 may be a foldable display device. The electronic device 10 may be folded outward or inward based on the folding axis FAX. In case that the electronic device is folded outward based on the folding axis FAX, the display surfaces of the electronic device 10 are respectively positioned outward in the third direction DR3, and images may be displayed in both directions. In case that the electronic device is folded inward based on the folding axis FAX, the display surface may not be visible from the outside.

According to some embodiments, the electronic device 10 may include a display area DA, a component area EA, and a non-display area PA. The display area DA may be divided into a 1-1 display area DA1-1, a 1-2 display area DA1-2, and a folding area FA. The 1-1 display area DA1-1 and the 1-2 display area DA1-2 may be respectively positioned on the left and right with respect to (or centered on) the folding axis FAX, and the folding area FA may be positioned between the 1-1 display area DA1-1 and the 1-2 display area DA1-2. At this time, in case that the electronic device is folded outward with respect to the folding axis FAX, the 1-1 display area DA1-1 and the 1-2 display area DA1-2 are positioned on both sides in the third direction DR3 and may display images in both directions. In addition, in case that the electronic device is folded inward with respect to the folding axis FAX, the 1-1 display area DA1-1 and the 1-2 display area DA1-2 may not be visible from the outside.

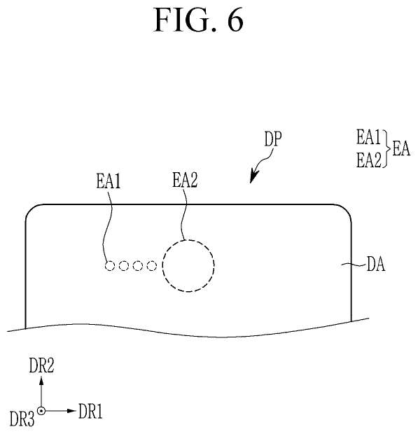

FIG. 6 is an enlarged plan view of a partial area of a display device according to some embodiments.

The display panel DP has a display area DA on the front surface, and may include a component area EA on the front surface, and specifically, may include a first component area EA1 and a second component area EA2. Additionally, in the embodiments of FIG. 6, a plurality of first component areas EA1 are positioned adjacent to the second component area EA2. In the embodiments of FIG. 6, the first component area EA1 is positioned to the left of the second component area EA2. The position and number of the first component areas EA1 may vary according to some embodiments. In FIG. 6, the optical element corresponding to the second component area EA2 may be a camera, and the optical element corresponding to the first component area EA1 may be a light sensor.

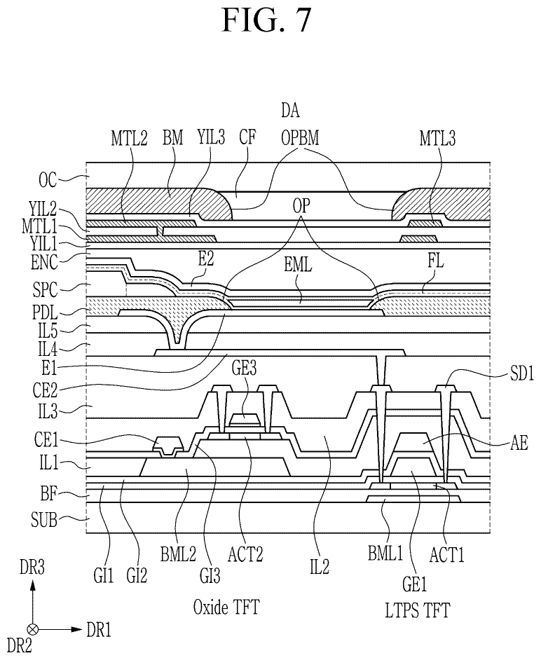

Hereinafter, a stacked structure of one pixel positioned in a display area according to some embodiments will be described with reference to FIG. 7. FIG. 7 is a cross-sectional view of a display panel corresponding to a display area. Description of the same components as the above-described components will be omitted.

Referring to FIG. 7, the substrate SUB may include a material having rigid characteristics such as glass or a flexible material that can be bent such as plastic or polyimide. On the substrate SUB according to some embodiments, a polycrystalline transistor (LTPS) corresponding to a first transistor and an oxide transistor (Oxide TFT) corresponding to a second transistor may be located.

A metal layer BML may be positioned on the substrate SUB. The metal layer BML may be located at a position overlapping a channel of a subsequent first semiconductor layer ACT1, and is also referred to as a lower shielding layer. The metal layer BML may include a metal or metal alloy such as copper (Cu), molybdenum (Mo), aluminum (Al), or titanium (Ti).

A buffer layer BF may be positioned on the substrate SUB and the metal layer BML. The buffer layer BF may planarize the surface of the substrate SUB and block penetration of impurity elements. The buffer layer BF may include an inorganic material, and for example, may include an inorganic insulating material such as silicon nitride (SiNx), silicon oxide (SiOx), or silicon oxynitride (SiOxNy).

A first semiconductor layer ACT1 may be positioned on the buffer layer BF. The first semiconductor layer ACT1 of the display device according to some embodiments may include amorphous silicon or polycrystalline silicon. Both sides of the channel of the first semiconductor layer ACT1 may be regions having conductive characteristics by plasma treatment or doping. Both sides of the channel of the first semiconductor layer ACT1 may serve as a first electrode or a second electrode of a transistor.

A first gate insulating layer GI1 may be positioned on the first semiconductor layer ACT1. The first gate insulating layer GI1 may cover the first semiconductor layer ACT1 and the substrate SUB. The first gate insulating layer GI1 may include an inorganic insulating material such as silicon nitride (SiNx), silicon oxide (SiOx), or silicon oxynitride (SiOxNy). The first gate insulating layer GI1 may be a single layer or multi-layer structure including the above inorganic insulating materials.

A first gate electrode GE1 may be positioned on the first gate insulating layer GI1. The first gate electrode GE1 may include a metal or metal alloy such as copper (Cu), molybdenum (Mo), aluminum (Al), silver (Ag), chromium (Cr), tantalum (Ta), or titanium (Ti). The first gate electrode GE1 may include a single layer or multiple layers. A region of the first semiconductor layer ACT1 overlapping the first gate electrode GE1 in a plan view may be a channel region.

A first scan line or a light emission control line may be positioned on the first gate conductive layer where the first gate electrode GE1 is positioned.

A second gate insulating layer GI2 may be positioned on the first gate electrode GE1. The second gate insulating layer GI2 may include an inorganic insulating material such as silicon nitride (SiNx), silicon oxide (SiOx), or silicon oxynitride (SiOxNy). The second gate insulating layer GI2 may be a single layer or multi-layer structure including the above inorganic insulating materials.

A capacitor electrode AE may be positioned on the second gate insulating layer GI2. The capacitor electrode AE may overlap the first gate electrode GE1 to form a capacitor.

Also, a lower shielding layer BML2 of an oxide transistor (Oxide TFT) may be positioned on the second gate insulating layer GI2. The lower shielding layer BML2 of the oxide transistor (Oxide TFT) may be positioned under the channel of the oxide transistor (Oxide TFT) to shield the channel from light or electromagnetic interference provided from below.

According to some embodiments, the second gate conductive layer including the lower shielding layer BML2 and the capacitor electrode AE may further include a scan line, a control line, or a voltage line. The second gate conductive layer may include a metal or metal alloy such as copper (Cu), molybdenum (Mo), aluminum (Al), or titanium (Ti), and may include a single layer or multiple layers.

A first insulating layer IL1 may be positioned on the capacitor electrode AE and the lower shielding layer BML2. The first insulating layer IL1 may include an inorganic insulating material such as silicon nitride (SiNx), silicon oxide (SiOx), or silicon oxynitride (SiOxNy). The first insulating layer IL1 may be a single layer or multi-layer structure including the above inorganic insulating materials.

A second semiconductor layer ACT2 including a channel, a first region, and a second region of an oxide transistor (Oxide TFT) may be positioned on the first insulating layer IL1. The second semiconductor layer ACT2 may include an oxide semiconductor.

A third gate insulating layer GI3 may be positioned on the second semiconductor layer ACT2. The third gate insulating layer GI3 may be positioned on the entire surface on the second semiconductor layer ACT2 and the first insulating layer IL1. The third gate insulating layer GI3 may include an inorganic insulating film including silicon oxide (SiOx), silicon nitride (SiNx), silicon oxynitride (SiONx), or the like.

A third gate conductive layer including a second gate electrode GE3 of an oxide transistor (Oxide TFT) may be positioned on the third gate insulating layer GI3. The second gate electrode GE3 of the oxide transistor (Oxide TFT) may overlap the channel of the second semiconductor layer ACT2. The third gate conductive layer may further include a scan line or a control line, and may additionally include a connection member CE1 connected to the lower shielding layer BML2 of the oxide transistor (Oxide TFT). The third gate conductive layer may include a metal or metal alloy such as copper (Cu), molybdenum (Mo), aluminum (Al), or titanium (Ti), and may include a single layer or multiple layers.

A second insulating layer IL2 may be positioned on the third gate conductive layer. The second insulating layer IL2 may have a single-layer or multi-layer structure. The second insulating layer IL2 may include an inorganic insulating material such as silicon nitride (SiNx), silicon oxide (SiOx), or silicon oxynitride (SiOxNy), and may include an organic material according to some embodiments.

A first data conductive layer SD1 including a connection member connectable to the first region and the second region of each of the polycrystalline transistor (LTPS TFT) and the oxide transistor (Oxide TFT) may be positioned on the second insulating layer IL2. The first data conductive layer SD1 may include a metal or metal alloy such as aluminum (Al), copper (Cu), molybdenum (Mo), titanium (Ti), and may include a single layer or multiple layers.

A third insulating layer IL3 may be positioned on the first data conductive layer SD1. The third insulating layer IL3 may be an organic insulating film including an organic material, and the organic material may include one or more materials selected from the group including polyimide, polyamide, acrylic resin, benzocyclobutene, and phenol resin.

A second data conductive layer including an anode connection member CE2 may be positioned on the third insulating layer IL3. The second data conductive layer may include a data line or a driving voltage line. The second data conductive layer may include a metal or metal alloy such as aluminum (Al), copper (Cu), molybdenum (Mo), or titanium (Ti), and may include a single layer or multiple layers.

A fourth insulating layer IL4 and a fifth insulating layer IL5 may be positioned on the second data conductive layer. An opening for anode connection is formed in the fourth insulating layer IL4 and the fifth insulating layer IL5. The anode connection member CE2 is electrically connected to the first electrode E1 through the opening for anode connection. The fourth insulating layer IL4 and the fifth insulating layer IL5 may be organic insulating films and may include one or more materials selected from the group consisting of polyimide, polyamide, acrylic resin, benzocyclobutene, and phenol resin. According to some embodiments, the fifth insulating layer IL5 may be omitted.

A first electrode E1 may be positioned on the fifth insulating layer IL5. The first electrode E1 is also referred to as an anode electrode and may include a single layer including a transparent conductive oxide film or a metal material or multiple layers including them. The transparent conductive oxide film may include ITO (Indium Tin Oxide), poly-ITO, IZO (Indium Zinc Oxide), IGZO (Indium Gallium Zinc Oxide), ITZO (Indium Tin Zinc Oxide), and the like. The metal material may include silver (Ag), molybdenum (Mo), copper (Cu), gold (Au), aluminum (Al), and the like. For example, the first electrode E1 may have a three-layer structure of ITO/Ag/ITO.

A pixel defining layer PDL may be positioned on the first electrode E1 and the fifth insulating layer IL5. The pixel defining layer PDL may overlap an edge of the first electrode E1 and may be spaced apart from a center of the first electrode E1. The pixel defining layer PDL may define a formation position of the light emitting layer EML so that the light emitting layer EML may be positioned on a portion where the upper surface of the first electrode E1 is exposed.

The pixel defining layer PDL may be an organic insulating layer including one or more materials selected from the group consisting of polyimide, polyamide, acrylic resin, benzocyclobutene, and phenol resin, and according to some embodiments, the pixel defining layer PDL may be formed as a black pixel defining layer (BPDL) including a black pigment.

A spacer SPC is positioned on the pixel defining layer PDL. The spacer SPC may include a first portion positioned in a high and narrow area and a second portion positioned in a low and wide area. Unlike the pixel defining layer PDL, the spacer SPC may be formed of a transparent organic insulating material. According to some embodiments, the spacer SPC may be formed of a positive type transparent organic material.

The light emitting layer EML may be positioned in the pixel opening OP of the pixel defining layer PDL. The light emitting layer EML may include an organic material that emits light such as red, green, or blue. The light emitting layer EML emitting red, green, or blue light may include a low molecular weight or high molecular weight organic material. Auxiliary layers FL such as an electron injection layer, an electron transport layer, a hole transport layer, and a hole injection layer may also be included above and below the light emitting layer EML, and a hole injection layer and a hole transport layer may be positioned below the light emitting layer EML, and an electron transport layer and an electron injection layer may be positioned above the light emitting layer EML.

The second electrode E2 may be positioned on the pixel defining layer PDL and the light emitting layer EML. The second electrode E2 is also referred to as a cathode electrode and may be formed as a transparent conductive layer including ITO (Indium Tin Oxide), IZO (Indium Zinc Oxide), IGZO (Indium Gallium Zinc Oxide), ITZO (Indium Tin Zinc Oxide), and the like. In addition, the second electrode E2 may have semi-transparent characteristics, and in this case, may form a micro cavity together with the first electrode E1. According to the micro cavity structure, light of a specific wavelength is emitted upward due to the spacing and characteristics between the two electrodes, and as a result, red, green, or blue may be displayed.

The first electrode E1, the light emitting layer EML, and the second electrode E2 may form one light emitting element.

An encapsulation layer ENC is positioned on the second electrode E2. The encapsulation layer ENC may include at least one inorganic film and at least one organic film, and according to some embodiments, may have a triple layer structure including a first inorganic encapsulation layer, an organic encapsulation layer, and a second inorganic encapsulation layer.

The encapsulation layer ENC may protect the light emitting layer EML formed of an organic material from moisture or oxygen that may be introduced from the outside. According to some embodiments, the encapsulation layer ENC may include a structure in which an inorganic layer and an organic layer are sequentially further stacked.

A touch sensing unit may be positioned on the encapsulation layer ENC.

The touch sensing unit according to some embodiments may include a plurality of sensing insulating layers YIL1, YIL2, and YIL3 and sensing electrodes MTL1, MTL2, and MTL3.

A lower sensing insulating layer YIL1 may be positioned on the encapsulation layer ENC. The lower sensing insulating layer YIL1 may be formed as an inorganic insulating layer. The inorganic material included in the inorganic insulating layer may be at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. According to some embodiments, the lower sensing insulating layer YIL1 may be omitted.

A sensing electrode connection portion MTL1, a first sensing insulating layer YIL2, and a plurality of sensing electrodes MTL2 and MTL3 may be positioned above the lower sensing insulating layer YIL1. The plurality of sensing electrodes MTL2 and MTL3 may be positioned on the same layer, and the sensing electrode connection portion MTL1 may be positioned on a different layer from the plurality of sensing electrodes MTL2 and MTL3.

The sensing electrode connection portion MTL1, the first sensing insulating layer YIL2, and the plurality of sensing electrodes MTL2 and MTL3 may constitute a sensing sensor. The sensing sensor may be classified into a resistive type, a capacitive type, an electro-magnetic type, an optical type, and the like. The sensing sensor according to some embodiments may use a capacitive type sensor.

The first sensing insulating layer YIL2 may be positioned between the sensing electrode connection portion MTL1 and the plurality of sensing electrodes MTL2 and MTL3. The first sensing insulating layer YIL2 may include an inorganic insulating material. The inorganic insulating material may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

A plurality of sensing electrodes MTL2 and MTL3 may be positioned on the first sensing insulating layer YIL2. The plurality of sensing electrodes MTL2 and MTL3 may include a plurality of first sensing electrodes MTL3 and a plurality of second sensing electrodes MTL2. The first sensing electrode MTL3 and the second sensing electrode MTL2 may be electrically insulated. The first sensing insulating layer YIL2 may include an opening exposing an upper surface of the sensing electrode connection portion MTL1. Through the opening of the first sensing insulating layer YIL2, the sensing electrode connection portion MTL1 may be connected to the second sensing electrode MTL2 to electrically connect two adjacent second sensing electrodes MTL2. In addition, the sensing electrode connection portion connecting the first sensing electrode MTL3 may be formed on the same layer as the first sensing electrode MTL3 and the second sensing electrode MTL2.

The plurality of sensing electrodes MTL2 and MTL3 may include a conductive material having good conductivity. For example, the plurality of sensing electrodes MTL2 and MTL3 may include a metal or metal alloy such as aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta). The plurality of sensing electrodes MTL2 and MTL3 may include a single layer or multiple layers. In this case, the plurality of sensing electrodes MTL2 and MTL3 may include an opening so that light emitted from the light emitting diode is emitted upward without interference. According to some embodiments, the plurality of sensing electrodes MTL2 and MTL3 may include a triple layer including an upper layer, an intermediate layer, and a lower layer, the upper layer and the lower layer may include titanium (Ti), and the intermediate layer may include aluminum (Al).

A second sensing insulating layer YIL3 may be positioned on the plurality of sensing electrodes MTL2 and MTL3. The second sensing insulating layer YIL3 may include an organic insulating material or an inorganic insulating material. The organic insulating material may include, for example, at least one of an acetate-based compound, an acrylic resin, a polyimide resin, a polyamide resin, or Alq₃[Tris(8-hydroxyquinolinato)aluminum].

The second sensing insulating layer YIL3 may cover the plurality of sensing electrodes MTL2 and MTL3 and the first sensing insulating layer YIL2. The second sensing insulating layer YIL3 may overlap most of the entire surface of the substrate SUB.

A color filter CF and a light blocking layer BM may be positioned on the second sensing insulating layer YIL3.

The color filter CF includes a red color filter that transmits red light, a green color filter that transmits green light, and a blue color filter that transmits blue light. Each color filter CF may be positioned to overlap the first electrode E1 of the light emitting diode in a plan view. Because light emitted from the light emitting layer EML may be emitted while being changed to the corresponding color while passing through the color filter, all light emitted from the light emitting layer EML may have the same color. However, the light emitting layer EML displays light of different colors, and the displayed color may be enhanced by passing through a color filter of the same color.

The color filter CF may be positioned in the light blocking opening OPBM of the light blocking layer BM. A light blocking layer BM may be positioned between adjacent color filters CF. The light blocking layer BM may overlap the pixel defining layer PDL. The light blocking layer BM may include a light blocking material that absorbs or blocks light.

However, the present disclosure is not limited thereto, and at least two color filters may overlap in a non-emission area corresponding to between adjacent pixels. For example, a blue color filter and a red color filter may overlap, or a blue color filter, a green color filter, and a red color filter may overlap to replace the light blocking layer.

An overcoat layer OC may be positioned on the color filter CF and the light blocking layer BM. The overcoat layer OC may planarize the upper surface of the touch sensing unit. The overcoat layer OC may be a transparent organic insulating layer including one or more materials selected from the group consisting of polyimide, polyamide, acrylic resin, benzocyclobutene, phenol resin, and acetate-based compounds.

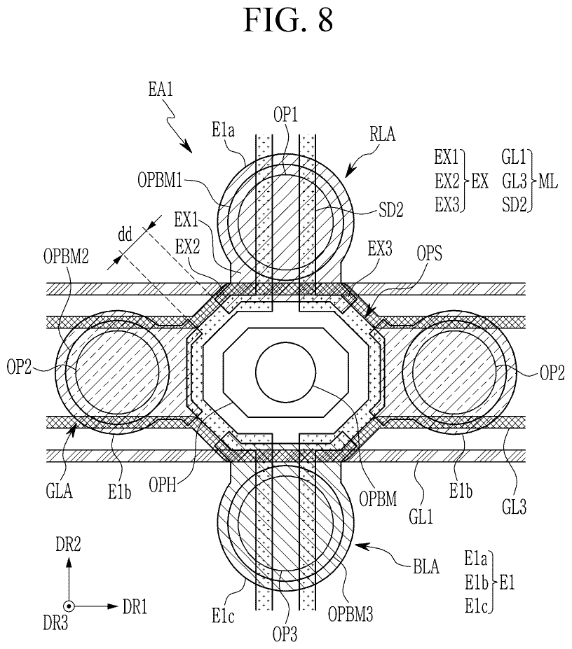

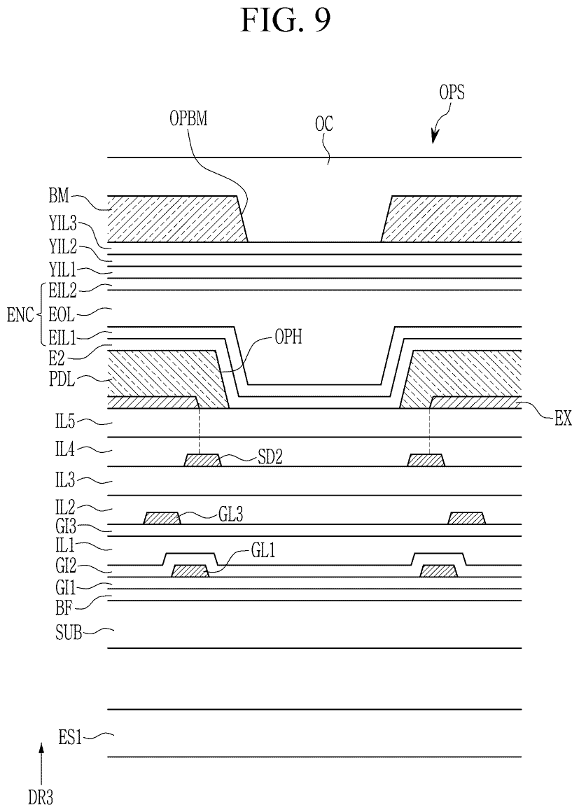

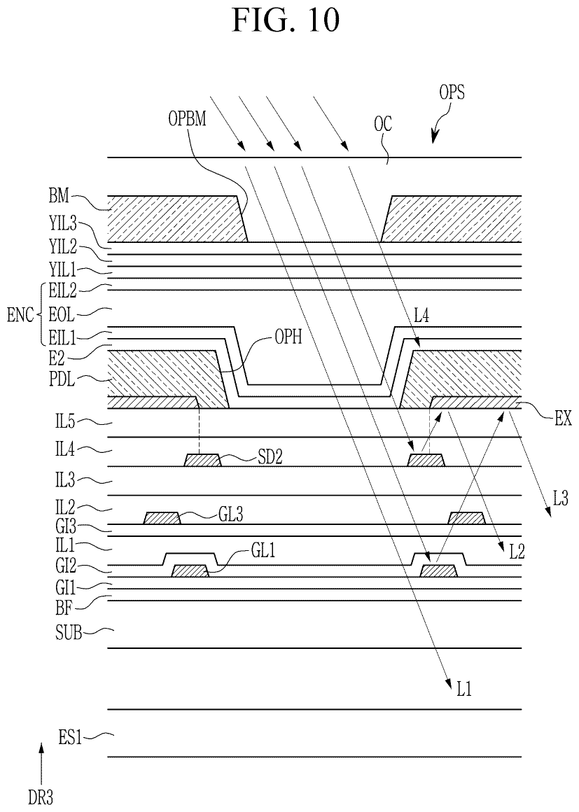

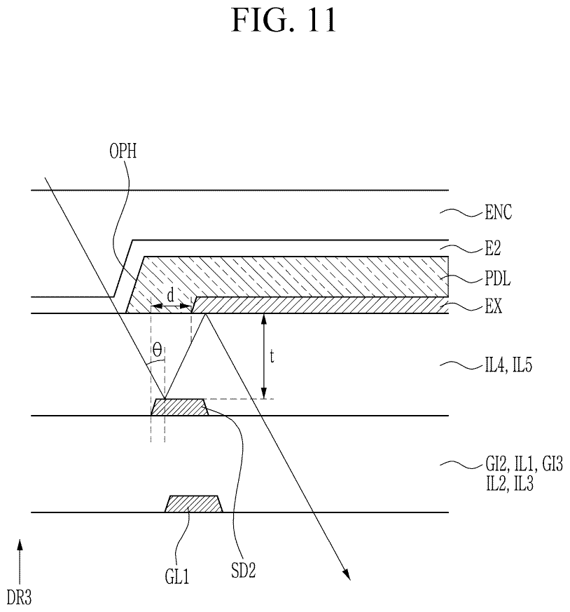

Hereinafter, a light sensor area according to some embodiments will be described in more detail with reference to FIGS. 8 to 11. FIG. 8 is a plan view of a first component area according to some embodiments, FIG. 9 is a cross-sectional view of a light sensor area according to some embodiments, FIG. 10 is a view illustrating a path of light incident in a light sensor area according to some embodiments, and FIG. 11 is a schematic cross-sectional view of a light sensor area according to some embodiments. Description of the same components as the above-described components will be omitted.

First, referring to FIG. 8, the first component area EA1 according to some embodiments may include a first color emission area RLA, a second color emission area GLA, a third color emission area BLA including light emitting elements and a light sensor area OPS. The first color emission area RLA, the second color emission area GLA, the third color emission area BLA, and the light sensor area OPS shown in FIG. 8 may be repeatedly arranged. The first component area EA1 may include a plurality of light sensor areas OPS.

The first color emission area RLA may emit red light and may be referred to as a red light emission area hereinafter. The second color emission area GLA may emit green light and may be referred to as a green light emission area hereinafter. The third color emission area BLA may emit blue light and may be referred to as a blue light emission area hereinafter. This specification illustrates embodiments in which two green light emission areas GLA are arranged along the first direction DR1, and a red light emission area RLA and a blue light emission area BLA are arranged along the second direction DR2, but is not limited to such an arrangement and may be modified into various arrangements.

The light blocking layer positioned in the red light emission area RLA may include a first light blocking opening OPBM1. The light blocking layer positioned in the green light emission area GLA may include a second light blocking opening OPBM2. The light blocking layer positioned in the blue light emission area BLA may include a third light blocking opening OPBM3. This specification illustrates embodiments in which the light blocking openings OPBM1, OPBM2, and OPBM3 are larger than the pixel openings OP1, OP2, and OP3, but is not limited thereto, and the sizes of the light blocking openings OPBM1, OPBM2, and OPBM3 may be variously modified.

The stacked structure of each of the red light emission area RLA, the green light emission area GLA, and the blue light emission area BLA may be the same as the stacked structure described in FIG. 7. Hereinafter, a detailed description will be omitted.

The red light emission area RLA according to some embodiments may include a 1-1 electrode E1a, the green light emission area may include a 1-2 electrode E1b, and the blue light emission area BLA may include a 1-3 electrode E1c. The 1-1 electrode E1a, the 1-2 electrode E1b, and the 1-3 electrode E1c may be referred to as the aforementioned first electrode.

The 1-1 electrode E1a may overlap the first pixel opening OP1, the 1-2 electrode E1b may overlap the second pixel opening OP2, and the 1-3 electrode E1c may overlap the third pixel opening OP3.

Each of the 1-1 electrode E1a, the 1-2 electrode E1b, and the 1-3 electrode E1c according to some embodiments may include an extension portion EX as shown in FIG. 8. The extension portion EX may extend toward the light sensor area OPS. The extension portion EX may be connected to each of the 1-1 electrode E1a, the 1-2 electrode E1b, and the 1-3 electrode E1c and may be integrally formed. The extension portion EX includes the same material as the 1-1 electrode E1a, the 1-2 electrode E1b, and the 1-3 electrode E1c, and may be manufactured in the same process.

The extension portion EX may include a first portion EX1 extending from the first pixel opening OP1 along the second direction (−DR2), and a second portion EX2 and a third portion EX3 protruding from the first portion EX1 in different diagonal directions. The second portion EX2 and the third portion EX3 may extend in different diagonal directions. The extension portion EX according to the present embodiments has been described as including the first portion EX1, the second portion EX2, and the third portion EX3, but is not limited thereto, and the extension portion EX may be provided in any shape for overlapping with the metal line ML.

At least a portion of the extension portion EX may overlap with the metal line ML. The extension portion EX may overlap with an outer edge of the metal line ML. The extension portion EX may be positioned along an edge of the metal line ML. The extension portion EX does not completely cover the metal line ML and may expose at least a portion thereof.

The metal line ML may include at least one of a first gate line GL1, a third gate line GL3, or a second data line SD2. The first gate line GL1 may be positioned on the same layer as the aforementioned first gate electrode (GE1 in FIG. 7) and may be formed through the same process. The third gate line GL3 may be positioned on the same layer as the second gate electrode (GE3 in FIG. 7) and may be formed through the same process. The second data line SD2 may be positioned on the same layer as the aforementioned anode connection member (CE2 in FIG. 7) and may be formed through the same process.

Adjacent first electrodes E1 may be spaced apart from each other. The 1-1 electrode E1a positioned in the red light emission area RLA and the 1-2 electrode E1b positioned in the green light emission area GLA may be spaced apart from each other. The 1-2 electrode E1b positioned in the green light emission area GLA and the 1-3 electrode E1c positioned in the blue light emission area BLA may be spaced apart from each other. A minimum separation distance dd between the 1-1 electrode E1a and the 1-2 electrode E1b may be about 4 micrometers or more. Also, a minimum separation distance between the 1-2 electrode E1b and the 1-3 electrode E1c may be about 4 micrometers or more. Alternatively, a minimum separation distance between the 1-1 electrode E1a and the 1-2 electrode E1b may be about 4.5 micrometers or more. Also, a minimum separation distance between the 1-2 electrode E1b and the 1-3 electrode E1c may be about 4.5 micrometers or more. That is, a minimum distance between adjacent extension portions EX may be about 4 micrometers or more, and for example, may be about 4.5 micrometers or more.

In case that the minimum separation distance between adjacent 1-1electrode E1a, 1-2 electrode E1b, and 1-3 electrode E1c does not satisfy the above numerical range, disconnection between adjacent first electrodes E1 may not be easy.

The red light emission area RLA, the green light emission area GLA, and the blue light emission area BLA may surround the light sensor area OPS. The light sensor area OPS may be an area through which light/signals emitted from an electronic component or light/signals incident to an electronic component are transmitted.

The light sensor area OPS is an area through which light may transmit, and may be an area where transistors and light emitting layers are not located. In the case of an electronic device according to some embodiments, in case that light is transmitted through the first component area EA1, the light transmittance may be about 10% or more, for example, 25% or more, 40% or more, 50% or more, 85% or more, or 90% or more. The pixel defining layer positioned in the light sensor area OPS may include a first opening OPH.

Because the first component area EA1 includes the light sensor area OPS, the resolution may be lower than that of the display area. Because the first component area EA1 includes the light sensor area OPS, the number of pixels that may be arranged per unit area may be less than the number of pixels arranged per unit area in the display area DA. For example, the resolution of the first component area EA1 may be about ½, ⅜, ⅓, ¼, 2/9, ⅛, 1/9, 1/16, or the like of the resolution of the display area DA. For example, the resolution of the display area DA may be about 400 ppi or more, and the resolution of the first component area EA1 may be about 200 ppi or about 100 ppi.

A metal line ML may be located in the light sensor area OPS according to some embodiments. The metal line ML may include, for example, at least one of a first gate line GL1, a third gate line GL3, or a second data line SD2. The metal line ML may have a shape surrounding the first opening OPH as shown in FIG. 8. However, it may have a shape that is broken in some areas while surrounding the first opening OPH, or the metal line ML may be provided in a closed loop shape according to some embodiments.

Each of the first gate line GL1 and the third gate line GL3 according to some embodiments may have a shape extending along the first direction DR1. Also, the second data line SD2 may have a shape extending along the second direction DR2. A combination of the second data line SD2 located on the right side, the first gate line GL1 or the third gate line GL3 located on the lower side, the second data line SD2 located on the left side, and the first gate line GL1 or the third gate line GL3 located on the upper side with reference to the drawing may surround the first opening OPH in a plan view.

The extension portion EX may overlap at least a portion of the metal line ML in a plan view. Also, a portion of the metal line ML may not overlap with the extension portion EX.

According to some embodiments, the extension portion EX protruding from the 1-1 electrode E1a may overlap with at least two second data lines SD2. Also, according to some embodiments, the extension portion EX protruding from the 1-1 electrode E1a may also overlap with portions of the first gate line GL1 and the third gate line GL3.

According to some embodiments, the extension portion EX protruding from the 1-2 electrode E1b may overlap with a portion of one second data line SD2 positioned on the left (or right) side in FIG. 8. Also, according to some embodiments, the extension portion EX protruding from the 1-2 electrode E1b may also overlap with portions of two first gate lines GL1 and portions of two third gate lines GL3.

According to some embodiments, the extension portion EX protruding from the 1-3 electrode E1c may overlap with at least two second data lines SD2. Also, according to some embodiments, the extension portion EX protruding from the 1-3 electrode E1c may also overlap with portions of the first gate line GL1 and portions of the third gate line GL3.

Also, adjacent extension portions EX may be spaced apart. A portion of the metal line ML may be exposed between the spaced extension portions EX. However, the arrangement relationship with the extension portion EX may be modified according to various forms of the metal line ML without being limited to these embodiments.

Hereinafter, the cross-sectional structure of the light sensor area will be described in more detail with reference to FIG. 9. FIG. 9 is a cross-sectional view of the light sensor area. Description of the same components as the above-described components will be omitted.

Referring to FIG. 9, a buffer layer BF, a first gate insulating layer GI1, a second gate insulating layer GI2, a first insulating layer IL1, a third gate insulating layer GI3, a second insulating layer IL2, a third insulating layer IL3, a fourth insulating layer IL4, and a fifth insulating layer IL5 extending from the display area may be positioned on the substrate SUB. An optical element ES1 may be positioned on the rear surface of the substrate SUB.

A first gate line GL1 may be positioned between the first gate insulating layer GI1 and the second gate insulating layer GI2. The first gate line GL1 may be positioned on the same layer as the first gate electrode positioned in the display area. The first gate line GL1 includes the same material as the first gate electrode and may be manufactured in the same process. According to some embodiments, the first gate line GL1 may be electrically connected to the first gate electrode.

A third gate line GL3 may be positioned between the third gate insulating layer GI3 and the second insulating layer IL2. The third gate line GL3 may be positioned on the same layer as the second gate electrode positioned in the display area. The third gate line GL3 includes the same material as the second gate electrode (third gate conductive layer) and may be manufactured in the same process. According to some embodiments, the third gate line GL3 may be electrically connected to the second gate electrode.

A second data line SD2 may be positioned between the third insulating layer IL3 and the fourth insulating layer IL4. The second data line SD2 may be positioned on the same layer as the anode connection electrode CE2 positioned in the display area. The second data line SD2 includes the same material as the anode connection electrode CE2 and may be manufactured in the same process.

Alternatively, but not limited thereto, a second gate conductive layer line positioned on the same layer as the capacitor electrode positioned in the display area may be positioned in the first component area EA1, or a first data conductive layer line positioned on the same layer as the first data conductive layer positioned in the display area may be positioned.

The metal line ML described in FIG. 8 may include at least one of a first gate line GL1, a third gate line GL3, a second data line SD2, a second gate conductive layer line, or a first data conductive layer line.

In FIG. 9, the second data line SD2 may be the line closest to the first opening OPH. However, the first gate line GL1 or the third gate line GL3 may be closest to the first opening OPH without being limited thereto.

According to some embodiments, the extension portion EX may overlap a portion of the second data line SD2. At least a portion of the second data line SD2 may not overlap with the extension portion EX in cross section.

The pixel defining layer PDL positioned in the light sensor area OPS may completely cover the extension portion EX. The pixel defining layer PDL may cover an end of the extension portion EX. The pixel defining layer PDL may include a first opening OPH through which light incident from the outside may be incident on the rear surface of the display panel. The first opening OPH of the pixel defining layer PDL may overlap with the light sensor area OPS.

A second electrode E2 extending from the display area may be positioned on the pixel defining layer PDL and the fifth insulating layer IL5. The second electrode E2 may be positioned in the first opening OPH. A separate light emitting layer may not be positioned in the light sensor area OPS. The second electrode E2 may contact the insulating layer IL5 exposed by the first opening OPH.

An encapsulation layer ENC, touch insulating layers YIL1, YIL2, and YIL3, a light blocking layer BM, and an overcoat layer OC extending from the display area may be positioned on the second electrode E2. A light blocking layer BM may be positioned between the overcoat layer OC and the third touch insulating layer YIL3.

The light blocking layer BM may include a light blocking opening OPBM. The size of the light blocking opening OPBM may be smaller than the size of the first opening OPH. The overcoat layer OC may fill the light blocking opening OPBM. However, the size of the light blocking opening OPBM may be larger than the size of the first opening OPH without being limited to these embodiments.

Hereinafter, a principle in which external light is incident on the rear surface of the display panel according to some embodiments will be described in more detail with reference to FIG. 10. FIG. 10 is a view illustrating a path of light in a light sensor area according to some embodiments.

Referring to FIG. 10, light incident from the outside may be incident on the light sensor area OPS through the light blocking opening OPBM. Some of them (L4) may be absorbed by the pixel defining layer PDL including a light blocking material.

Light incident on the first gate line GL1 may be reflected from the first gate line GL1 and may be incident on the extension portion EX, and may be reflected again from the extension portion EX and emitted to the rear surface of the display panel (L3).

Also, light incident on the second data line SD2 may be reflected from the second data line SD2 and incident on the extension portion EX, and may be reflected again from the extension portion EX and emitted to the rear surface of the display panel (L2).

Also, a portion of light incident into the light blocking opening OPBM and the first opening OPH may pass through the substrate SUB and be directly emitted to the rear surface of the display panel (L1).

According to some embodiments, the extension portion extending from the first electrode may reflect a portion of light incident on the pixel defining layer that absorbs light in the light sensor area back to the rear surface of the display panel, thus increasing the amount of light emitted to the rear surface of the display panel. Light incident on the rear surface of the display panel may be incident on the optical element ES1.

Next, the separation distance between the metal line and the extension portion will be described with reference to FIG. 11. FIG. 11 is a cross-sectional view showing some components in a display device according to some embodiments.

Referring to FIG. 11, a distance d between an end of the second data line SD2 and an end of the extension portion EX may satisfy Equation (1) below.

$$d < t \cdot tan Θ \qquad Equation ( 1 )$$

In Equation (1), t is the shortest distance between the upper surface of the second data line SD2 and the lower surface of the extension portion EX. In Equation (1), Θ is the incident angle of light incident on the second data line SD2. The end of the extension portion EX may be covered by the pixel defining layer PDL and may be spaced apart from the second data line SD2 by the distance d derived through Equation (1).

As an example, let us consider a case where the refractive index of the insulating layer is 1.64 and t is 2.45 micrometers. Light incident at 60 degrees from the outside of the display panel may be incident at about 31.9 degrees due to the refractive index of the insulating layer. By substituting 2.45 for t and 31.9 for Θ in Equation (1), d can be derived as 1.52. Therefore, the distance d between the end of the second data line SD2 and the end of the extension portion EX may be up to about 1.52 micrometers.

At this time, the distance d has been described based on the second data line SD2, but is not limited thereto.

As an example, substitution may be made in Equation (1) based on the first gate line GL1 adjacent to the first opening OPH. The distance d between the end of the first gate line GL1 and the end of the extension portion EX may be derived through the incident angle Θ of light incident on the first gate line GL1 and the shortest distance t between the upper surface of the first gate line GL1 and the lower surface of the extension portion EX. The positional relationship of the third gate line or other data conductive layer lines may also be derived through the aforementioned Equation (1).

As described above, various d values may be derived based on metal lines located on various layers, and any one of them may be selected to determine the arrangement of the extension portion EX.

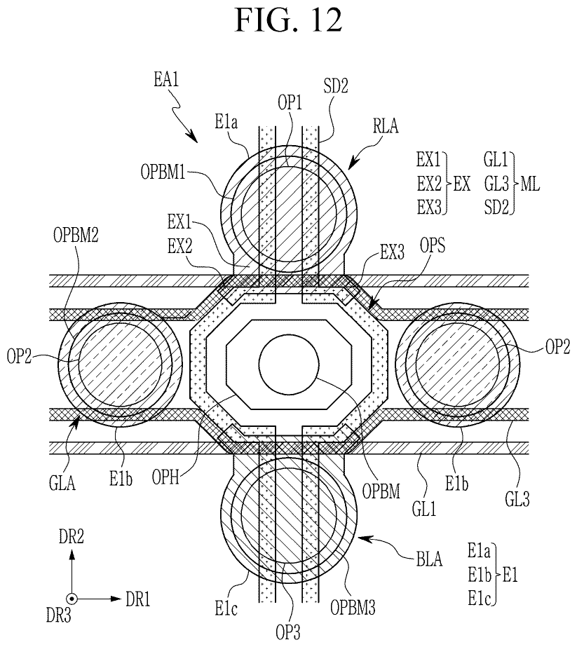

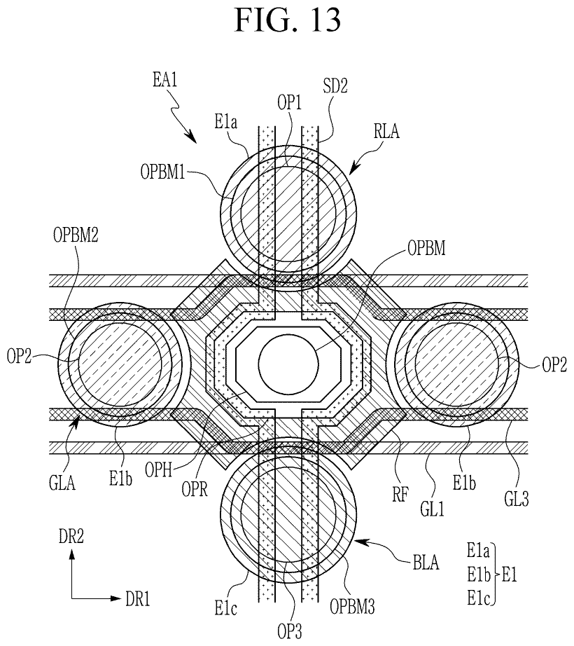

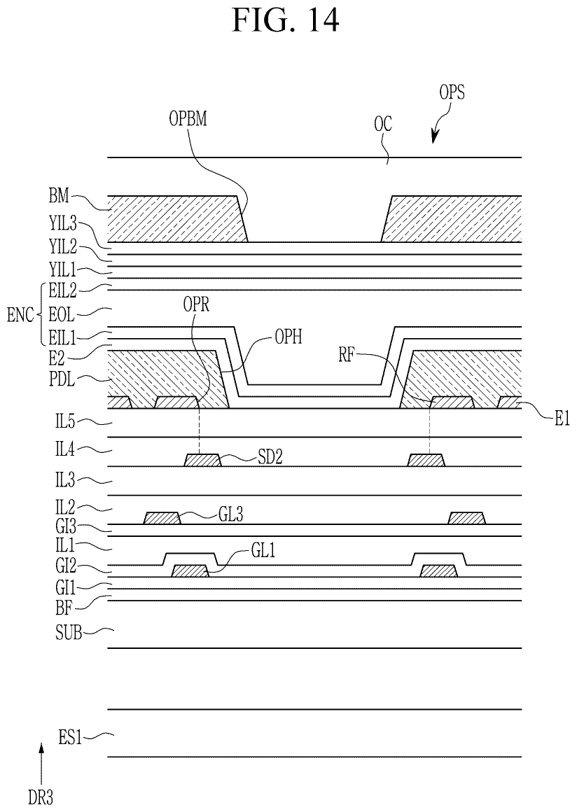

Next, a display device according to some embodiments will be described in more detail with reference to FIGS. 12 to 14. FIG. 12 is a plan view of a first component area according to some embodiments, FIG. 13 is a plan view of a first component area according to some embodiments, and FIG. 14 is a schematic cross-sectional view of a light sensor area according to some embodiments. Description of the same components as the above-described components will be omitted.

First, referring to FIG. 12, the first component area EA1 according to some embodiments may include a red light emission area RLA, a green light emission area GLA, and a blue light emission area BLA. A 1-1 electrode E1a may be positioned in the red light emission area RLA. A 1-2 electrode E1b may be positioned in the green light emission area GLA. A 1-3 electrode E1c may be positioned in the blue light emission area BLA.

According to some embodiments, at least one of the plurality of first electrodes E1a, E1b, or E1c may include an extension portion EX. For example, the 1-1 electrode E1a and the 1-3 electrode E1c may include the extension portion EX, and the 1-2 electrode E1b may not include the extension portion.

Referring to FIG. 12, the first opening OPH according to some embodiments may have an octagonal shape in a plan view. At this time, a width of the first opening OPH along the first direction DR1 may be greater than a width of the first opening OPH along the second direction DR2. An amount of light incident along the second direction DR2 may be relatively smaller than an amount of light incident along the first direction DR1. To compensate for this, each of the 1-1 electrode E1a and the 1-3 electrode E1c positioned adjacently along the second direction DR2 may include the extension portion EX.

However, the shape of the opening of the light sensor area OPS is not limited thereto and may be variously modified, and at least one of the plurality of first electrodes E1a, E1b, or E1c may be modified to include the extension portion EX according to user needs.

According to some embodiments, the extension portions EX arranged adjacently along the second direction DR2 may overlap with at least one of the first gate line GL1, the third gate line GL3, or the second data line SD2. According to some embodiments, the extension portion EX may expose at least a portion of the second data line SD2. The exposed second data line SD2 may be positioned between the first opening OPH and the 1-1 opening OP1 in a plan view. Alternatively, the exposed second data line SD2 may be positioned between the first opening OPH and the 1-3 opening OP3 in a plan view.

Next, referring to FIGS. 13 and 14, the first component area EA1 according to some embodiments may include a red light emission area RLA, a green light emission area GLA, and a blue light emission area BLA. A 1-1 electrode E1a may be positioned in the red light emission area RLA. A 1-2 electrode E1b may be positioned in the green light emission area GLA. A 1-3 electrode E1c may be positioned in the blue light emission area BLA.

The 1-1 electrode E1a may have substantially the same planar shape as the first pixel opening OP1 overlapping the 1-1 electrode E1a. The 1-2 electrode E1b may have substantially the same planar shape as the second pixel opening OP2 overlapping the 1-2 electrode E1b. The 1-3 electrode E1c may have substantially the same planar shape as the third pixel opening OP3 overlapping the 1-3 electrode E1c.

Each of the 1-1 electrode E1a, the 1-2 electrode E1b, and the 1-3 electrode E1c may further include a protrusion for electrical connection with a transistor. Also, according to some embodiments, the first pixel opening OP1, the second pixel opening OP2, and the third pixel opening OP3 may have a circular shape, and the 1-1 electrode E1a, the 1-2 electrode E1b, and the 1-3 electrode E1c may have a circular shape. However, the shape is not limited thereto, and the opening and the first electrode may be modified into various shapes such as a circle, an ellipse, and a polygon.

A reflective layer RF may be located in the light sensor area OPS between adjacent 1-1 electrode E1a, 1-2 electrode E1b, and 1-3 electrode E1c. The reflective layer RF may be surrounded by one 1-1 electrode E1a, two 1-2 electrodes E1b, and one 1-3 electrode E1c. The reflective layer RF is spaced apart from the 1-1 electrode E1a, the 1-2 electrode E1b, and the 1-3 electrode E1c and may not receive a voltage. The reflective layer RF may be in a floating state.

The reflective layer RF may include the same material as the 1-1 electrode E1a, the 1-2 electrode E1b, and the 1-3 electrode E1c. The reflective layer RF may be manufactured in the same process as the 1-1 electrode E1a, the 1-2 electrode E1b, and the 1-3 electrode E1c and may be positioned on the same layer.

The reflective layer RF may surround the first opening OPH. The reflective layer RF may overlap at least a portion of the metal line ML. The reflective layer RF may include a second opening OPR. The second opening OPR may be larger than the first opening OPH in a plan view. The reflective layer RF may surround the light blocking opening OPBM, but is not limited thereto.

Next, referring to FIG. 14, a distance d between an end of the metal line ML and an end of the reflective layer RF may satisfy Equation (1) below.

$$d < t \cdot tan Θ \qquad Equation ( 1 )$$

In Equation (1), t is the shortest distance between an upper surface of the metal line ML and a lower surface of the reflective layer RF. In Equation (1), Θ is an incident angle of light on the metal line ML.

An end of the reflective layer RF may be covered by the pixel defining layer PDL and may be spaced apart from the metal line ML by the distance d derived through Equation (1). At this time, the distance d has been described based on the second data line SD2, but is not limited thereto.

Various d values may be derived based on metal lines arranged at various positions, and any one of them may be selected to determine the arrangement of the reflective layer RF.

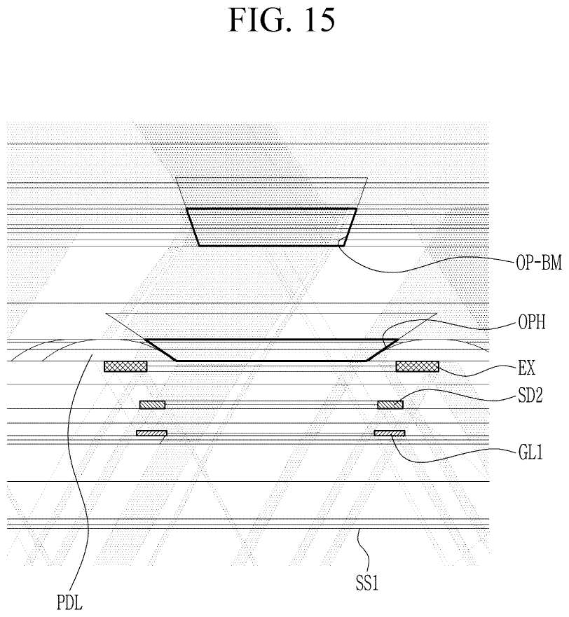

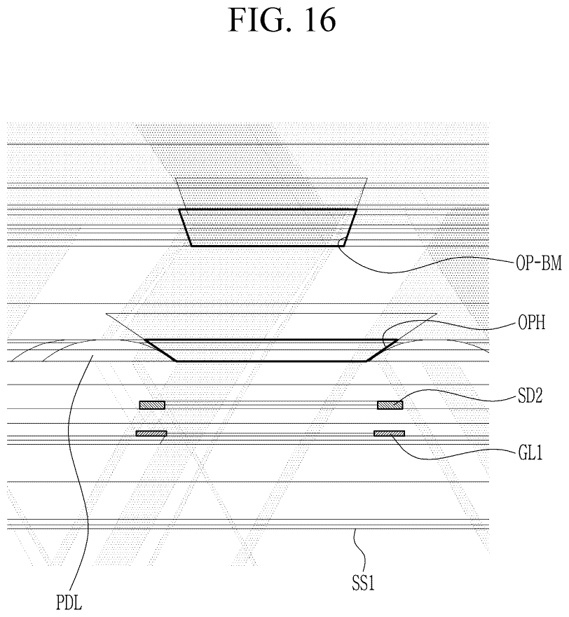

Hereinafter, the amount of light emitted to the rear surface of the display panel in the display device according to some embodiments and the comparative example will be described with reference to FIGS. 15 to 16. FIG. 15 is a schematic diagram illustrating light incident on a display panel according to some embodiments, and FIG. 16 is a schematic diagram illustrating light incident on a display panel according to a comparative example.

FIGS. 15 and 16 show some components of the display panel. FIGS. 15 and 16 show a first gate line GL1 corresponding to a metal line, a second data line SD2, an extension portion EX extending from a first electrode, a first opening OPH of a pixel defining layer, and a light blocking opening OP-BM of a light blocking layer.

In FIGS. 15 and 16, light incident from the outside is indicated by lines. It was confirmed that in the case of the display panel according to some embodiments (FIG. 15), a relatively large amount of light is emitted based on the rear surface SS1 of the display panel compared to the display panel according to the comparative example (FIG. 16). Therefore, the amount of light incident on the optical element positioned on the rear surface of the display panel may increase, and accordingly, the performance and reliability of the display device may be relatively improved.

Although aspects of some embodiments of the present disclosure have been described in detail above, the scope of embodiments according to the present disclosure is not limited thereto, and various modifications and improvements by those skilled in the art using the concept of embodiments according to the present disclosure as defined in the following claims, and their equivalents, also fall in the scope of the present disclosure.

### Description of Some of the Reference Symbols

DA: display area
EA: component area
DP: display panel
ES: optical element
SUB: substrate
E1: first electrode
PDL: pixel defining layer
EML: light emitting layer
E2: second electrode
OPS: light sensor area
ML: metal line
EX: extension portion
IL1, IL2: insulating layer
RLA: red light emission area
GLA: green light emission area
BLA: blue light emission area
ACT: semiconductor layer
GE1: gate electrode
SE: source electrode
DE: drain electrode
RF: reflective layer

What is claimed is:

1. A display device comprising:
a display panel including a display area and a component area surrounded by the display area and including a plurality of light sensor areas; and
an optical element on a rear surface of the component area,
wherein the display area includes:
a transistor on a substrate,
a first electrode on the transistor,
a pixel defining layer overlapping a portion of the first electrode,
a light emitting layer overlapping the first electrode, and
a second electrode on the light emitting layer,
wherein the light sensor area includes:
a metal line on the substrate,
an extension portion extending from the first electrode,
an insulating layer between the metal line and the extension portion,
the pixel defining layer on the extension portion and including a first opening, and a second electrode on the pixel defining layer,
wherein the extension portion overlaps at least a portion of the metal line in a plan view.

2. The display device of claim 1, wherein the first component area includes a red light emission area, a green light emission area, and a blue light emission area.

3. The display device of claim 1, wherein the extension portion includes:
a first portion extending from the first electrode toward the first opening in the plan view, and
a second portion and a third portion respectively protruding from the first portion,
wherein the first portion is between the second portion and the third portion.

4. The display device of claim 3, wherein the second portion and the third portion protrude in different directions.

5. The display device of claim 3, wherein each of the first portion, the second portion, and the third portion overlaps at least a portion of the metal line.

6. The display device of claim 3, wherein the extension portion is arranged along an edge of the metal line.

7. The display device of claim 1,
wherein the transistor includes a first transistor and a second transistor,
the first transistor includes:
a first semiconductor layer on the substrate, and
a first gate electrode overlapping a portion of the first semiconductor layer,
the second transistor includes:
a second semiconductor layer on the first gate electrode, and
a second gate electrode overlapping a portion of the second semiconductor layer.

8. The display device of claim 7, further comprising:
a first data conductive layer on the second gate electrode, and
a second data conductive layer between the first data conductive layer and the first electrode,
wherein the metal line is on a same layer as at least one of the first gate electrode, the second gate electrode, or the second data conductive layer.

9. The display device of claim 1, wherein the pixel defining layer in the light sensor area covers an end of the extension portion.

10. The display device of claim 1, wherein the second electrode extending from the display area contacts the insulating layer at the first opening.

11. A display device comprising:
a display panel including a display area and a component area surrounded by the display area and including a plurality of light sensor areas; and
an optical element on a rear surface of the component area,
wherein the display area includes:
a transistor on a substrate,
a first electrode on the transistor,
a pixel defining layer overlapping a portion of the first electrode,
a light emitting layer overlapping the first electrode, and
a second electrode on the light emitting layer,
wherein the light sensor area includes:
the pixel defining layer extending from the display area and including a first opening,
a reflective layer between adjacent first electrodes and surrounding the first opening, and
a second electrode on the pixel defining layer,
wherein the reflective layer is on a same layer as the first electrode and spaced apart from the first electrode.

12. The display device of claim 11, wherein the reflective layer includes a second opening, and a size of the second opening is larger than a size of the first opening.

13. The display device of claim 11, wherein the first component area includes a red light emission area, a green light emission area, and a blue light emission area, and
the reflective layer is between the red light emission area, the green light emission area, and the blue light emission area.

14. The display device of claim 11, wherein the transistor includes a first transistor and a second transistor,
the first transistor includes:
a first semiconductor layer on the substrate; and
a first gate electrode overlapping a portion of the first semiconductor layer, and
the second transistor includes:
a second semiconductor layer on the first gate electrode; and
a second gate electrode overlapping a portion of the second semiconductor layer.

15. The display device of claim 14, wherein the reflective layer overlaps at least a portion of the metal line.

16. The display device of claim 15, further comprising:
a first data conductive layer on the second gate electrode, and
a second data conductive layer between the first data conductive layer and the first electrode,
wherein the metal line is on a same layer as at least one of the first gate electrode, the second gate electrode, or the second data conductive layer.

17. The display device of claim 14, further comprising an insulating layer between the metal line and the reflective layer,
wherein a distance (d) between an end of the metal line and an end of the reflective layer satisfies the following equation (1):
$$d < t \cdot tan Θ \qquad Equation ( 1 )$$
wherein in equation (1), t is a minimum distance between an upper surface of the metal line and a lower surface of the reflective layer, and Θ is an incident angle of light on the metal line.

18. The display device of claim 17, wherein the insulating layer includes at least two layers.

19. The display device of claim 11, wherein the pixel defining layer in the light sensor area covers an end of the reflective layer.

20. An electronic device comprising a display device,
the display device comprising:
a display panel including a display area and a component area surrounded by the display area and including a plurality of light sensor areas; and
an optical element on a rear surface of the component area,
wherein the display area includes:
a transistor on a substrate,
a first electrode on the transistor,
a pixel defining layer overlapping a portion of the first electrode,
a light emitting layer overlapping the first electrode, and
a second electrode on the light emitting layer,
wherein the light sensor area includes:
a metal line on the substrate,
an extension portion extending from the first electrode,
the pixel defining layer on the extension portion and including a first opening, and
a second electrode on the pixel defining layer,
wherein the extension portion overlaps at least a portion of the metal line.
